(19) United States
(12) Patent Application Publication
(10) Pub. No.: US 2013/0087792 A1
(43) Pub. Date: Apr. 11, 2013

(54) PIXEL STRUCTURE OF REFLECTIVE TYPE ELECTROPHORETIC DISPLAY DEVICE AND METHOD OF MAKING THE SAME

(71) Applicants: Hsien-Kun Chiu, Taoyuan County (TW); Yi-Wei Lin, Taipei City (TW); Ming-Tsung Chung, Taoyuan County (TW); Ying-Tsung Tu, Taoyuan County (TW)

(72) Inventors: Hsien-Kun Chiu, Taoyuan County (TW); Yi-Wei Lin, Taipei City (TW); Ming-Tsung Chung, Taoyuan County (TW); Ying-Tsung Tu, Taoyuan County (TW)

(21) Appl. No.: 13/434,779

(22) Filed: Mar. 29, 2012

(30) Foreign Application Priority Data
Oct. 5, 2011 (TW) 100136167

(51) Int. Cl. H01L 29/786; H01L 33/60

(52) U.S. Cl. 257/59; 438/29; 257/E33.072; 257/E29.273

(57) ABSTRACT

The present invention provides a method of making a pixel structure of a reflective type electrophoretic display device. First, a first metal pattern layer, an insulating layer, a semiconductor pattern layer and a second metal pattern layer are formed sequentially on a substrate. Next, a passivation layer is formed on the substrate, the semiconductor pattern layer and the second metal pattern layer, and an organic photoresist layer is formed on the passivation layer, wherein the organic photoresist layer has a first contact hole exposing the passivation layer. Then, the organic photoresist layer is utilized as a mask to remove the exposed passivation layer and to form a second contact hole in the passivation layer to expose the second metal pattern layer. Subsequently, a third metal pattern layer and a transparent conductive pattern are formed sequentially on the organic photoresist pattern layer and the exposed second metal pattern layer.

### BACKGROUND OF THE INVENTION

1. Field of the Invention

The present invention relates to a pixel structure of an electrophoretic display device and a method of making the same, and more particularly, to a pixel structure of a reflective type electrophoretic display device and a method of making the same.

2. Description of the Prior Art

With the development of the technology, various types of flat display devices, such as liquid crystal display, organic light-emitting diode display, and plasma display, etc., have gradually replaced the traditional cathode ray tube display. Recently, an electrophoretic display device, also called electronic paper, is developed in display field to provide a display that is thinner, lighter, flexible and more easily carried.

Generally, an active matrix electrophoretic display device includes thin-film transistor matrix disposed under pixel electrodes. When a gate of the thin-film transistor in one pixel region is turned on, the pixel electrode would be charged to move corresponding charged particles upward or downward. In the manufacturing process of the active matrix electrophoretic display device, the steps of forming the gate of the thin-film transistor, the semiconductor layer, the source and drain of the thin-film transistor, the passivation layer, the photoresist layer, the reflective electrode, and the pixel electrode are required masks to be patterned, and are totally required seven masks to be completed. However, the number of the masks affects the manufacturing cost of the active matrix electrophoretic display device. For this reason, in the manufacturing method of the active matrix electrophoretic display device, to decrease the number of the masks used in the method of making the pixel structure of the reflective type electrophoretic display device to reduce the manufacturing cost of the active matrix electrophoretic display device is an important objective in this field.

### SUMMARY OF THE INVENTION

It is therefore one of the objectives of the present invention to provide a pixel structure of a reflective type electrophoretic display device and a method of making the same to reduce the number of the masks used in the method to decrease manufacturing cost.

According to the present invention, a method of making a pixel structure of a reflective type electrophoretic display device is provided. First, a substrate is provided. Then, a first patterned metal layer is formed on the substrate. Subsequently, an insulating layer is formed on the first patterned metal layer and the substrate. Next, a patterned semiconductor layer and a second patterned metal layer are formed on the insulating layer. Thereafter, a passivation layer is formed to cover the substrate, the patterned semiconductor layer and the second patterned metal layer. Then, a patterned organic photoresist layer is formed on the passivation layer, and the patterned organic photoresist layer has a first contact hole exposing the passivation layer. Next, the exposed passivation layer is removed by utilizing the patterned organic photoresist layer as a mask to form a second contact hole in the passivation layer, and the second contact hole exposes the second patterned metal layer. Afterward, a third patterned metal layer is formed on the patterned organic photoresist layer and the exposed second patterned metal layer. Then, a patterned transparent conductive layer is formed on the patterned metal layer, and the patterned transparent conductive layer covers the third patterned metal layer.

According to the present invention, a pixel structure of a reflective type electrophoretic display device is provided. The pixel structure includes a substrate, a thin-film transistor, a patterned organic photoresist layer, a passivation layer, a patterned metal layer, and a patterned transparent conductive layer. The thin-film transistor is disposed on the substrate, and the thin-film transistor has a gate, a source, and a drain. The patterned organic photoresist layer is disposed on the substrate and the thin-film transistor, and the patterned organic photoresist layer has a first contact hole. The passivation layer is disposed between the substrate and the patterned organic photoresist layer, and the passivation layer has a second contact hole, wherein the first contact hole is disposed corresponding to the second contact hole. The patterned metal layer is disposed on the patterned organic photoresist layer, and the patterned metal layer is in contact with the drain via the first contact hole and the second contact hole. The patterned transparent conductive layer is disposed on the patterned metal layer.

The present invention utilizes the halftone mask to form the patterned photoresist layer having different thicknesses, and utilizes the patterned organic photoresist layer as a mask to form the second contact hole, so that only five masks are required to form the pixel structure of the reflective electrophoretic display device. Accordingly, the number of the used masks can be effectively reduced, and the manufacturing cost can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 9 are schematic diagrams illustrating a method of making a pixel structure of a reflective type electrophoretic display device according to a preferred embodiment of the present invention.

FIG. 10 is a schematic diagram illustrating a top view of the pixel structure of the reflective type electrophoretic display device according to the preferred embodiment of the present invention.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to . . . ” Also, the term “electrically connect” is intended to mean either an indirect or direct electrical connection. Accordingly, if one device is coupled to another device, that connection maybe through a direct electrical connection, or through an indirect electrical connection via other devices and connections.

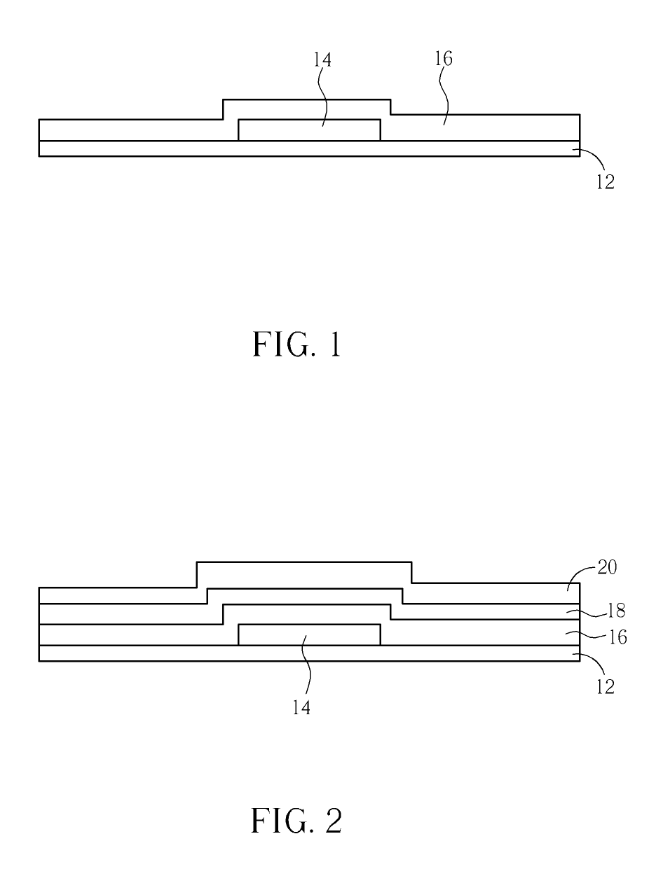

Please refer to FIG. 1 through FIG. 9. FIG. 1 through FIG. 9 are schematic diagrams illustrating a method of making a pixel structure of a reflective type electrophoretic display device according to a preferred embodiment of the present invention. The reflective type electrophoretic display device has a plurality of pixel structures, and each pixel structure is respectively disposed in a pixel region. In order to detail the method of the present invention, one pixel structure in single pixel region is taken as an example in the following description. As shown in FIG. 1, a substrate, such as glass substrate, is first provided. Then, a first metal layer is formed to cover the substrate 12. Thereafter, a first mask is utilized to pattern the first metal layer so as to form a first patterned metal layer 14. Next, an insulating layer 16, such as oxide or nitride, is formed to cover the substrate 12 and the first patterned metal layer 14. In this embodiment, the step of forming the insulating layer 16 may utilize a deposition process, such as physical evaporation deposition process or chemical evaporation deposition process, but is not limited herein.

As shown in FIG. 2, next, a semiconductor layer 18 and a second metal layer 20 are sequentially formed on the insulating layer 16. In this embodiment, the semiconductor layer 18 may include a amorphous silicon layer and a p-type doped or n-type doped amorphous silicon layer, and the step of forming the semiconductor layer 18 may forming an amorphous silicon layer on the insulating layer 16, and then, performing an ion-implantation process to implant p-type ions or n-type ions in the amorphous silicon layer so as to form the p-type doped or n-type doped amorphous silicon layer, but the present invention is not limited herein.

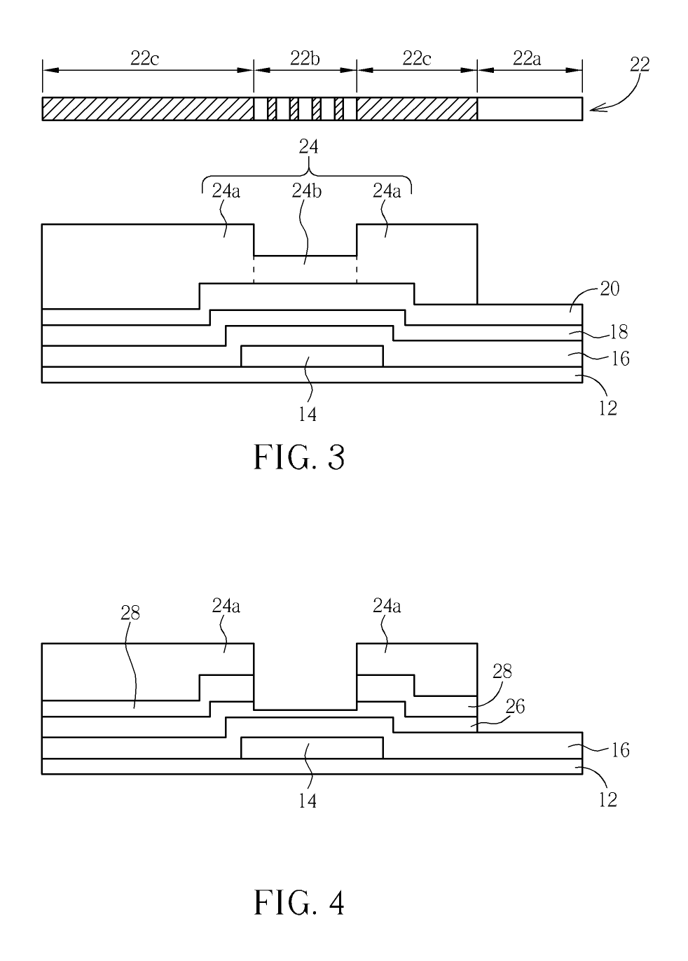

As shown in FIG. 3, subsequently, a photoresist layer is formed on the second metal layer 20. Then, a halftone mask 22 is disposed on the photoresist layer, and the halftone mask 22 is utilized to be a second mask to etch the photoresist layer so as to form a patterned photoresist layer 24 on the second metal layer 20 and expose the second metal layer 20. The halftone mask 22 has a transparent region 22a, a semi-transparent region 22b, and a light-shield region 22c, and the formed patterned photoresist layer 24 has a first part 24a disposed corresponding to the light-shield region 22c, and a second part 24b disposed corresponding to the half transparent region 22b. A thickness of the first part 24a is larger than a thickness of the second part 24b.

As shown in FIG. 4, an etching process is then performed through utilizing the patterned photoresist layer 24 as a mask to remove the second metal layer 20 and the semiconductor layer 18 disposed corresponding to the transparent region 22a and the second part 24b disposed corresponding to the semi-transparent region 22b so as to expose the second part 24b under the second metal layer 20. Subsequently, an etching solution having high selectivity between the insulating layer 16 and the second metal layer 20 is utilized to remove the exposed second metal layer 20 and a part of the semiconductor layer 18 so as to form a patterned semiconductor layer 26 and a second patterned metal layer 28. It should be noted that the halftone mask 22 is utilized to form the patterned photoresist layer 24 having different thicknesses in this embodiment, so that the second part 24b may be removed before the first part 22b. Thus, the second metal layer 20 under the second part 24b and the part of the semiconductor layer 28 maybe removed by continuously performing the etching process.

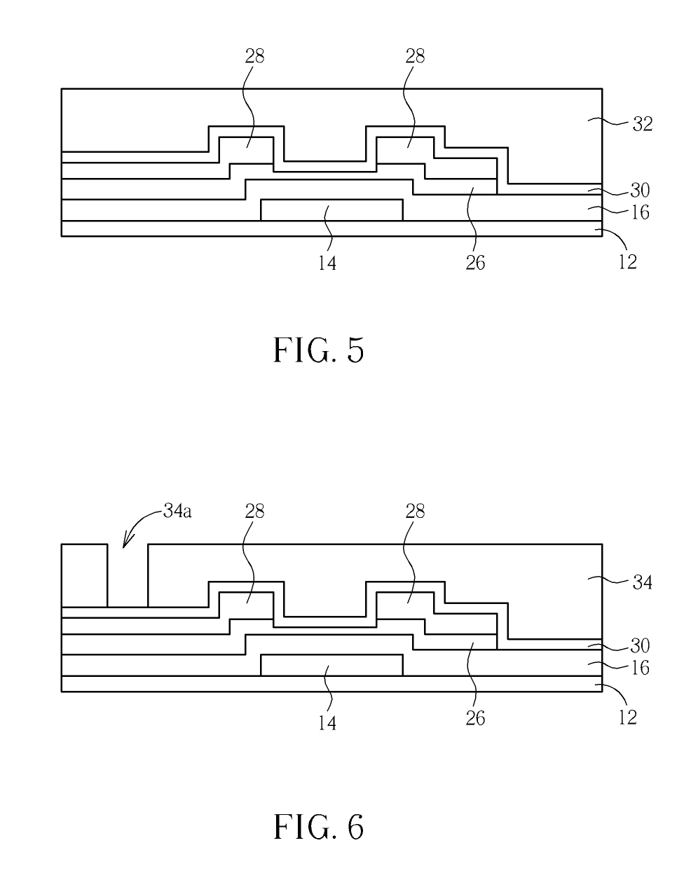

As shown in FIG. 5, the first part 24a of the patterned photoresist layer 24 is removed, and then, a deposition process is performed to form a passivation, such as silicon nitride, to cover the substrate 12, the patterned semiconductor layer 26, and the second patterned metal layer 28. Next, another deposition process is performed to form an organic photoresist layer 32 on the passivation layer 30.

As shown in FIG. 6, a third mask is utilized to pattern the organic photoresist layer 32 to form a patterned organic photoresist layer 34, and the patterned organic photoresist layer 34 has a contact hole 34a exposing the passivation layer 30.

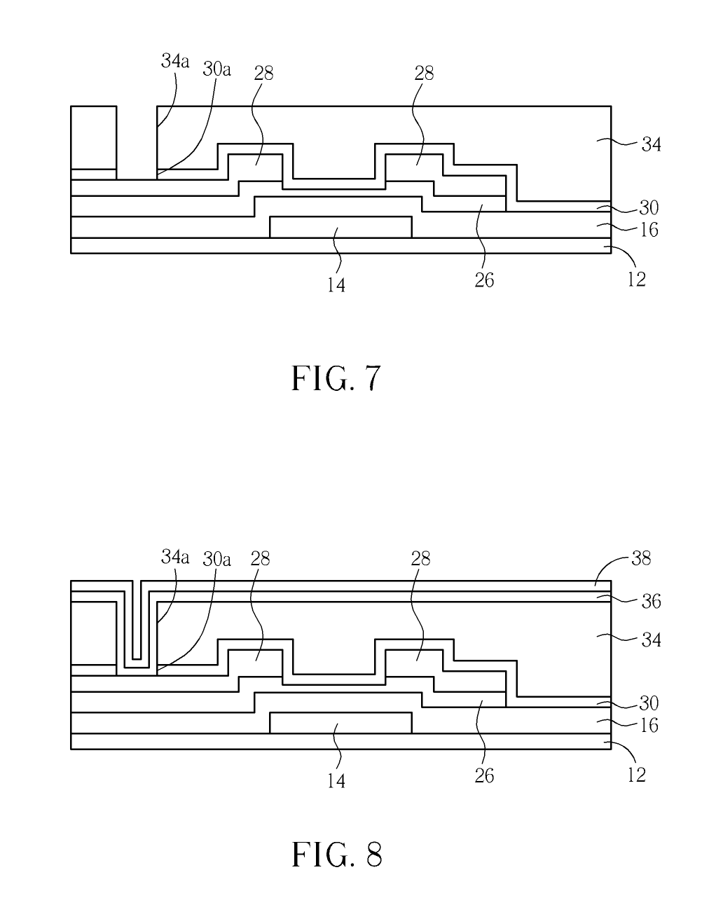

As shown in FIG. 7, thereafter, the patterned organic photoresist layer 34a is cured to harden the patterned photoresist layer 34a, and then, may be utilized to be a hard mask. For example, a semi-product having the patterned organic photoresist layer is positioned in an oven that has a temperature, about 220 degrees, but the present invention is not limited herein. Then, the patterned organic photoresist layer is utilized to be a mask to remove the exposed passivation layer 30 so as to form a second contact hole 30a in the passivation layer 30, and the second contact hole 30a exposes the second patterned metal layer 28. Since the second contact hole 30a is etched through the patterned photoresist layer 34a, a width of the first contact hole 34a and a width of the second contact hole 30a are the same, but the present invention is not limited to the above-mentioned description.

As shown in FIG. 8, a third metal layer is then deposited on the patterned organic photoresist layer 34a and the exposed second patterned metal layer 28. The third metal layer extends into the first contact hole 34a and the second contact hole 30a, and covers the exposed second patterned metal layer 28 to be in contact with the second patterned metal layer 28. In addition, a fourth mask is utilized to pattern the third metal layer so as to form the third patterned metal layer 36 on the patterned organic photoresist layer 34a and the second patterned metal layer 28. Next, a transparent conductive layer, such as indium zinc oxide (IZO) or indium tin oxide (ITO), is deposited on the third patterned metal layer 36. Thereafter, a fifth mask is utilized to pattern the transparent conductive layer to form a patterned transparent conductive layer 38 on the third patterned metal layer 36.

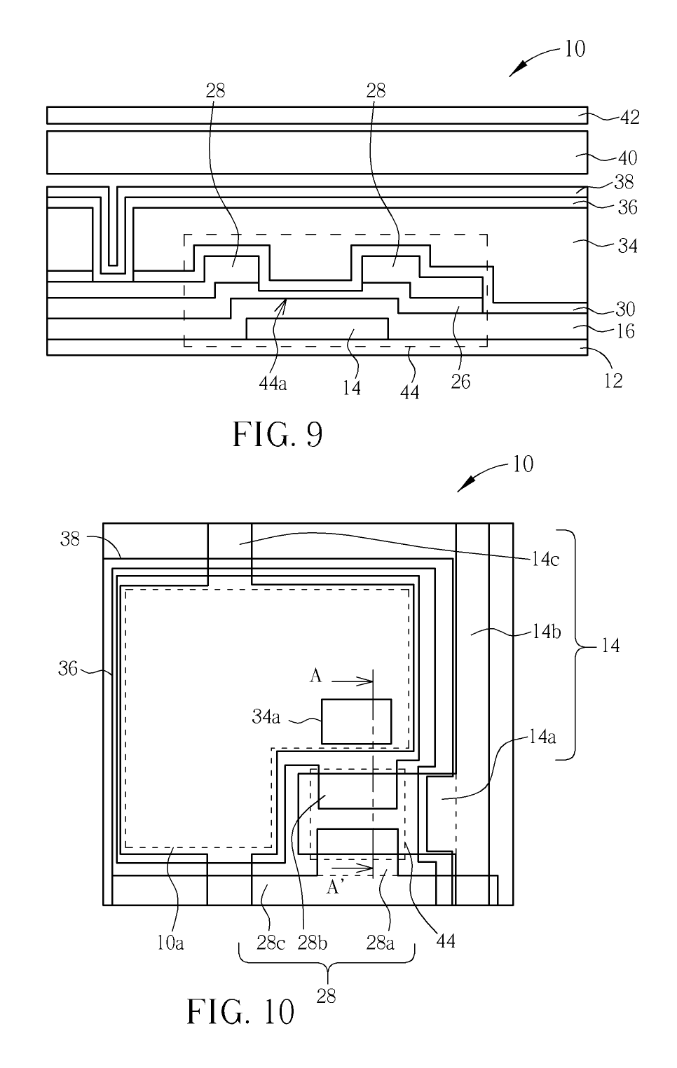

As shown in FIG. 9, an electrophoretic display film 40 is subsequently formed to cover the patterned transparent conductive layer 38, and a protective film 42 is formed to cover the electrophoretic display film 40 and protect the electrophoretic display film 40. Thus, the pixel structure 10 of the reflective type electrophoretic display device of this embodiment is completed.

It should be noted that the halftone mask 22 is utilized to form the patterned photoresist layer 24 having different thicknesses in this embodiment. Thus, the patterned semiconductor layer 26 and the second patterned metal layer 28 maybe formed in the same etching process, and extra one mask for removing the second part 24b under the patterned semiconductor layer 26 and the second patterned metal layer 28 under the second part 24b can be eliminated. Furthermore, in this embodiment, the patterned organic photoresist layer 34 is further utilized as a mask to form the second contact hole 30a, so that extra one mask for forming the second contact hole 30a can be further eliminated. As we can see from the above-mentioned description, only five masks are required to form the pixel structure 10 of the reflective electrophoretic display device. Accordingly, the number of the masks used in the method of making the pixel structure of the reflective type electrophoretic display device can be effectively reduced, and the manufacturing cost can be reduced.

The pixel structure of the reflective type electrophoretic display device in this embodiment is further detailed in the following description. Please refer to FIG. 10 together with FIG. 9. FIG. 10 is a schematic diagram illustrating a top view of the pixel structure of the reflective type electrophoretic display device according to the preferred embodiment of the present invention, and FIG. 9 is a schematic diagram illustrating a cross-sectional view of FIG. 10 taken along a cutting line A-A′. As shown in FIG. 9 and FIG. 10, the pixel structure 10 of the reflective type electrophoretic display device in this embodiment includes the substrate 12, the first patterned metal layer 14, the insulating layer 16, the patterned semiconductor layer 26, the second patterned metal layer 28, the patterned organic photoresist layer 34, the passivation layer 30, the third patterned metal layer 36, the patterned transparent conductive layer 38, the electrophoretic display film 40, and the protective film 42. In this embodiment, the first patterned metal layer 14 includes a gate 14a of a thin-film transistor 44, a scan line 14b, and a common line 14c, and the second patterned metal layer 28 includes a source 28a and a drain 28b of the thin-film transistor 44, and a data line 28c. The insulating layer 16 serves as agate insulating layer of the thin-film transistor 44, and the patterned semiconductor layer 26 disposed between the source 28a and the drain 28b serves as a channel region 44a of the thin-film transistor 44. In addition, the gate 14a is electrically connected to the scan line 14b, so that a scan signal can be transferred to the gate 14a through the scan line 14b. The source 28a is electrically connected to the data line 28c. It should be noted that the semi-transparent region 22b of the halftone mask 22 is disposed corresponding to a position of the gate 14a, and the light-shield region 22c is disposed corresponding to positions of the source 28a, the drain 28b and the data line 28c. Accordingly, the first part 24a of the patterned photoresist layer 24 is disposed over the source 28a, the drain 28b and the data line 28c, and the second part 24b of the patterned photoresist layer 24 is disposed over the patterned semiconductor layer 26 serving as the channel region 44a. For this reason, no extra mask is required to remove the semiconductor layer and the second metal layer over the channel region 44a, and one mask can be eliminated. Furthermore, the third patterned metal layer 36 covers an aperture region 10a of the whole pixel structure 10 so as to reflect a light from the outside. Thus, the reflective type electrophoretic display device can be operated under an environment with light, and the reflective type electrophoretic display device has no backlight. In addition, the patterned transparent conductive layer 38 covers the third patterned metal layer 36, so that the third patterned metal layer 36 would not be peeled or corroded. In this embodiment, the electrophoretic display film 40 includes a plurality of charged black particles and a dielectric liquid. Positions of the charged black particles are controlled through adjusting a voltage of the patterned transparent conductive layer 38 to display a white and black frame. Moreover, the protective film 42 can be utilized to protect the electrophoretic display film 40, so that the electrophoretic display film 40 can be avoided scraping.

In summary, the present invention utilizes the halftone mask to form the patterned photoresist layer having different thicknesses, and utilizes the patterned organic photoresist layer as a mask to form the second contact hole, so that only five masks are required to form the pixel structure of the reflective electrophoretic display device. Accordingly, the number of the masks used in the method of making the pixel structure of the reflective type electrophoretic display device can be effectively reduced, and the manufacturing cost can be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of making a pixel structure of a reflective type electrophoretic display device, comprising:
providing a substrate;
forming a first patterned metal layer on the substrate;
forming an insulating layer on the first patterned metal layer and the substrate;
forming a patterned semiconductor layer and a second patterned metal layer on the insulating layer;
forming a passivation layer to cover the substrate, the patterned semiconductor layer and the second patterned metal layer;
forming a patterned organic photoresist layer on the passivation layer, and the patterned organic photoresist layer having a first contact hole exposing the passivation layer;
removing the exposed passivation layer by utilizing the patterned organic photoresist layer as a mask to form a second contact hole in the passivation layer, and the second contact hole exposing the second patterned metal layer;
forming a third patterned metal layer on the patterned organic photoresist layer and the exposed second patterned metal layer; and
forming a patterned transparent conductive layer on the patterned metal layer, and the patterned transparent conductive layer covering the third patterned metal layer.

2. The method of making a pixel structure of a reflective type electrophoretic display device according to claim 1, wherein a width of the first contact hole is the same as a width of the second contact hole.

3. The method of making a pixel structure of a reflective type electrophoretic display device according to claim 1, wherein the step of forming the patterned semiconductor layer and the second patterned metal layer comprises:
forming a semiconductor layer and a metal layer sequentially on the insulating layer;
forming a patterned photoresist layer on the metal layer through utilizing a half-tone mask to expose the metal layer, wherein the patterned photoresist layer has a first part and a second part, and a thickness of the first part is larger than a thickness of the second part; and
removing the exposed metal layer, the second part, and the metal layer and a part of the semiconductor layer under the second part by utilizing the patterned photoresist layer as another mask to form the patterned semiconductor layer and the second patterned metal layer.

4. The method of making a pixel structure of a reflective type electrophoretic display device according to claim 3, wherein the first patterned metal layer comprises a gate, and the second part is disposed over the gate.

5. The method of making a pixel structure of a reflective type electrophoretic display device according to claim 1, further comprising curing the patterned organic photoresist layer between the step of forming the patterned organic photoresist layer and the step of removing the exposed passivation layer.

6. The method of making a pixel structure of a reflective type electrophoretic display device according to claim 1, further comprising forming an electrophoretic display film to cover the patterned transparent conductive layer.

7. The method of making a pixel structure of a reflective type electrophoretic display device according to claim 6, further comprising forming a protective film to cover the electrophoretic display film.

8. A pixel structure of a reflective type electrophoretic display device, comprising:
a substrate;
a thin-film transistor, disposed on the substrate, and the thin-film transistor having a gate, a source, and a drain;
a patterned organic photoresist layer, disposed on the substrate and the thin-film transistor, and the patterned organic photoresist layer having a first contact hole;
a passivation layer, disposed between the substrate and the patterned organic photoresist layer, and the passivation layer having a second contact hole, wherein the first contact hole is disposed corresponding to the second contact hole;
a patterned metal layer, disposed on the patterned organic photoresist layer, and the patterned metal layer being in contact with the drain via the first contact hole and the second contact hole; and
a patterned transparent conductive layer, disposed on the patterned metal layer.

9. The pixel structure of a reflective type electrophoretic display device according to claim 8, further comprising an electrophoretic display film, disposed on the patterned transparent conductive layer.

10. The pixel structure of a reflective type electrophoretic display device according to claim 9, further comprising a protective film, disposed on the electrophoretic display film.
